(19) United States
(12) Patent Application Publication
(10) Pub. No.: US 2023/0240016 A1
(43) Pub. Date: Jul. 27, 2023

(54) Method Of Forming Conductive Pattern

(71) Applicant: SEIKO EPSON CORPORATION, Tokyo (JP)

(72) Inventors: Toshimitsu HIRAI, Hokuto (JP); Hironori HASEI, Azumino (JP); Tatsuya FUJII, Suwa (JP)

(21) Appl. No.: 18/157,172

(22) Filed: Jan. 20, 2023

(30) Foreign Application Priority Data
Jan. 21, 2022 (JP) 2022-007692

(51) Int. Cl. H05K 3/12; H05K 1/09; H05K 1/03

(52) U.S. Cl. CPC H05K 3/125; H05K 1/097; H05K 1/0306; H05K 3/38

(57) ABSTRACT

A method of forming a conductive pattern includes forming a conductive pattern by ejecting a liquid-state material containing conductive fine particles onto a porous base material, wherein the conductive fine particles have an average particle size of from 1 nm to 200 nm, and the porous base material is formed with a plurality of cavities and includes communication holes through which the plurality of cavities are in communication, an average diameter of the communication holes being less than or equal to the average particle size of the conductive fine particles.

The present application is based on, and claims priority from JP Application Serial Number 2022-007692, filed Jan. 21, 2022, the disclosure of which is hereby incorporated by reference herein in its entirety.

### BACKGROUND

### 1. Technical Field

The present disclosure relates to a method of forming a conductive pattern.

### 2. Related Art

A technique has been proposed for forming a conductive pattern by ejecting a liquid-state material containing conductive fine particles onto a substrate. JP-A-2004-6578 describes a technique for forming a conductive pattern by ejecting a liquid-state material for wiring formation containing metal nanoparticles onto a substrate provided with a microvoid-type accommodation layer. This method allows for efficient thickening of conductive pattern.

Meanwhile, JP-A-2017-226777 discloses a porous film used in a battery separator such as that in a lithium battery. According to JP-A-2017-226777, applications of the porous film include battery separators in lithium batteries and the like, separators in electrolytic capacitors, electrolyte membranes in fuel cells and the like, electrode materials in batteries, separation membranes for gas or liquid, low dielectric constant materials, and various filters. JP-A-2017-226777 also describes that the average cavity diameter may in a range of from 0.01 μm (10 nm) to 2.5 μm (2500 nm).

However, there is room for improvement for the technique described in JP-A-2004-6578 because, in some cases, the adhesion of the conductive pattern printed on the surface of the accommodation layer may not be sufficient. Furthermore, it is conceivable to use a substrate that is porous instead of a substrate having an accommodation layer; however, JP-A-2017-226777 does not mention or suggest using a porous film as a substrate for wiring, nor does it mention or suggest what kind of porousness is suitable for improving the adhesion of the conductive pattern.

In other words, there has been a demand for a method of forming a conductive pattern having excellent adhesion with respect to a substrate.

### SUMMARY

A method of forming a conductive pattern according to an aspect of the present application includes forming a conductive pattern by ejecting a liquid-state material containing conductive fine particles onto a porous base material, wherein the conductive fine particles have an average particle size of from 1 nm to 200 nm, and the porous base material contains a plurality of cavities formed therein and communication holes through which the plurality of cavities are in communication, an average diameter of the communication holes being less than or equal to the average particle size of the conductive fine particles.

### BRIEF DESCRIPTION OF THE DRAWINGS

FIG. 1 is a view of one aspect of a method of forming a conductive pattern according to First Embodiment.

FIG. 2 is an enlarged view of a surface of a base material at a portion J in FIG. 1.

FIG. 3 is an enlarged view of a droplet that has landed.

FIG. 4 is an enlarged view of a droplet that has landed on a non-porous base material.

FIG. 5 is an exploded perspective view of a droplet ejecting head.

FIG. 6 is a cross-sectional view of the droplet ejecting head.

FIG. 7 is an enlarged view of a portion K in FIG. 2.

FIG. 8 is a plan view illustrating a conductive pattern created by the formation method of an example.

FIG. 9 is a plan view illustrating a conductive pattern of a comparative example.

FIG. 10 is a plan view illustrating a conductive pattern of the comparative example.

FIG. 11 is an external view of a smart phone.

FIG. 12 is an external view of a laptop.

FIG. 13 is an external view of a smart watch.

FIG. 14 is an exploded perspective view of a non-contact card medium.

### DESCRIPTION OF EXEMPLARY EMBODIMENTS

### First Embodiment

### Overview of Method of Forming Conductive Pattern

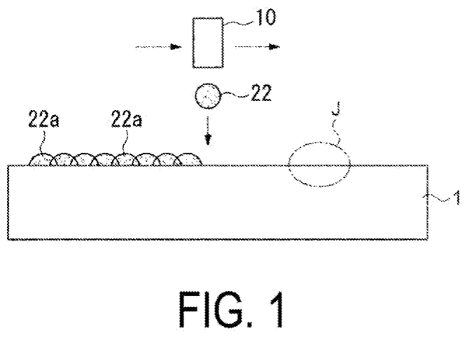

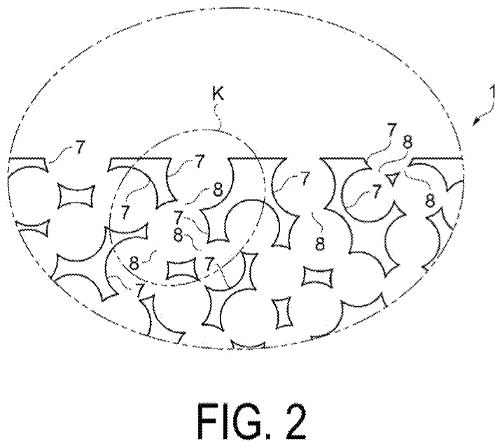

FIG. 1 is a view of one aspect of a method of forming a conductive pattern. FIG. 2 is an enlarged view of a surface of a base material at a portion J in FIG. 1.

Embodiments of the present disclosure will be described below with reference to the accompanying drawings.

As illustrated in FIG. 1, in the method of forming a conductive pattern of the present embodiment, a plurality of droplets 22 are ejected by a droplet ejecting head 10 onto a surface of a base material 1 to form the shape of a desired pattern, such as the shape of a wiring pattern to be formed. Here, as illustrated in FIG. 2, the base material 1 is a porous base material having a porous structure. In a preferred example, the base material 1 is a polyimide substrate having a porous structure, and the base material 1 has a plurality of cavities 7 and communication holes 8 via which adjacent cavities 7 communicate with each other. The plurality of cavities 7 is substantially spherical. Although the plurality of cavities 7 are formed irregularly, their diameters are substantially the same. Such a porous base material can be produced, for example, by the production method of JP-A-2017-226777. Note that the production method of the porous base material is not limited to the method above, and a production method capable of forming a similar porous structure may be used.

In a preferred example, as shown in FIG. 1, the droplet 22 is ejected from the droplet ejecting head 10 and lands on the surface of the base material 1, and a droplet 22a that has landed is in contact with the adjacent droplet 22a. Note that three or more droplets 22a in succession may be in contact with each other and partially overlapped. In the following description, an ink that forms the droplet 22 is referred to as a liquid-state material.

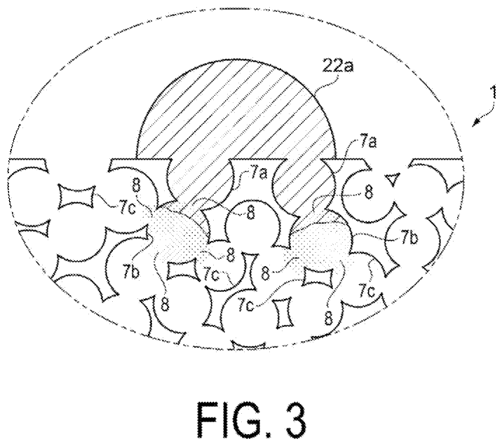

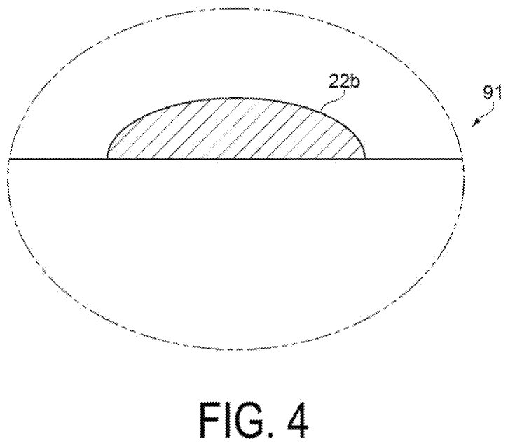

FIG. 3 is an enlarged view of a droplet that has landed. FIG. 4 is a view for comparison illustrating an enlarged view of a droplet that has landed on a non-porous base material.

FIG. 3 is an enlarged cross-sectional view of the droplet 22a that has landed on the base material 1 according to the formation method of the present embodiment. As illustrated in FIG. 3, a portion of the droplet 22a that has landed enters a plurality of cavities 7a that open to the surface of the base material 1 and fills the plurality of cavities 7a. Note that a cavity that opens to the surface of the base material 1 is referred to as a “cavity 7a”, a cavity that communicates with a cavity 7a via a communication hole 8 is referred to as a “cavity 7b”, and a cavity that communicates with a cavity 7b via a communication hole 8 is referred to as a “cavity 7c”. In other words, a cavity that communicates with the cavity 7a, located in the outermost surface, inside the base material 1 is referred to as the cavity 7b or the cavity 7c.

In the liquid-state material that has entered the cavities 7a, a dispersion medium with a high fluidity enters the adjacent cavities 7b through the communication holes 8. Furthermore, a portion of the dispersion medium enters the adjacent cavities 7c through the communication holes 8. In other words, a portion of the dispersion medium enters a plurality of cavities 7b and cavities 7c that communicate with the cavities 7a.

That is, in the droplet 22a that has landed on the base material 1 having a porous structure, the dispersion medium with a high fluidity enters a large number of cavities 7b and 7c through the communication holes 8 and is rapidly absorbed, while a large amount of a solid component, such as conductive particles and a binder, remains on the surface of the base material 1. Here, since a large portion of the dispersion medium with a high fluidity is absorbed by the cavities 7, wetting and spreading of the solid component on the surface is suppressed, and the diameter of the droplet at the time of landing is substantially maintained. As a result, a conductive pattern having a desired two-dimensional shape can be obtained.

In addition, in the liquid-state material that has entered the cavities 7a, nearly all conductive particles are not able to pass through the communication holes 8 and remain in the cavities 7a. After being sintered, the solid component including the conductive particles that remain in the cavities 7a exert an anchor effect and play a role of improving the adhesion of the conductive pattern with respect to the base material 1.

In contrast, as illustrated in FIG. 4, after a droplet 22b lands on a base material 91 that is plain and non-porous, there is almost no entry of the droplet 22b into the base material 91. As such, the droplet 22b spreads on a surface of the base material 91, resulting in a wider droplet compared to the droplet 22a in FIG. 3. Note that the base material 91 is a plain polyimide substrate that is not surface-treated, and the volume of the liquid-state material ejected (droplet 22) is the same for both the droplet 22a and the droplet 22b.

When the droplet 22b of FIG. 4 is sintered to form a conductive pattern, the resulting conductive pattern is wider than the shape of the desired pattern and has bleeding around the edges. The adhesion strength of the resulting conductive pattern is also insufficient.

Overview of Ejecting Device

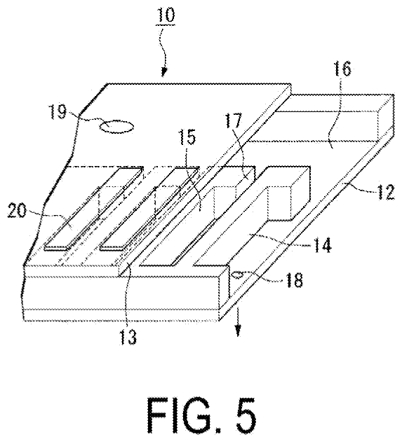

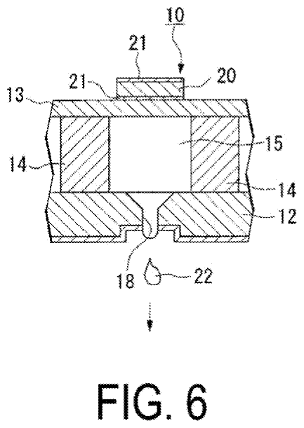

FIG. 5 is an exploded perspective view of a droplet ejecting head. FIG. 6 is a cross-sectional view of the droplet ejecting head.

The droplet ejecting head 10, which is an ejecting head of an ink jet device, includes a nozzle plate 12, a partition member 14, and a vibrating plate 13.

As illustrated in FIG. 5, the nozzle plate 12 is a stainless-steel nozzle plate and includes a plurality of nozzle holes 18 for ejecting the liquid-state material serving as an ink, for example.

The partition member 14 is provided with a plurality of walls for partitioning a plurality of pressure chambers 15, and is disposed between the nozzle plate 12 and the vibrating plate 13. Each of the pressure chambers 15 is provided with one of the nozzle holes 18. The partition member 14 also forms a reservoir 16 in which the liquid-state material is pooled.

The vibrating plate 13 is a member that serves as a lid of the plurality of pressure chambers 15 as well as the reservoir 16. A plurality of piezoelectric elements 20 are attached to the upper surface of the vibrating plate 13. Each of the pressure chambers 15 is provided with one of the piezoelectric elements 20. The pressure chamber 15 and the reservoir 16 communicate with each other via a supplying port 17. When the reservoir 16 is filled with the liquid-state material, the liquid-state material is supplied to each of the pressure chambers 15 from the reservoir 16. Furthermore, the liquid-state material is supplied to the reservoir 16 via a supplying hole 19 provided on the vibrating plate 13.

As illustrated in FIG. 6, when a drive voltage is applied to the piezoelectric element 20 in the droplet ejecting head 10, the piezoelectric element 20 deforms, which in turn causes the vibrating plate 13 to flex. As such, the pressure inside the pressure chamber 15 increases, and the increasing pressure causes the liquid-state material inside the pressure chamber 15 to be ejected from the nozzle hole 18. Note that the ejection is not limited to a liquid-state material jet method using the droplet ejecting head 10, and any ejecting method that satisfies the following suitable conditions may be used, or a known droplet ejecting method may be used.

Droplet Volume, Flying Speed

A nozzle diameter of the nozzle hole 18 in the droplet ejecting head 10 serving as an ejecting unit is preferably from 10 μm to 25 μm. Also, a volume of the droplet 22 ejected every time from the droplet ejecting head 10 is preferably from 0.2 pl to 20 pl. Furthermore, a flying speed of the droplet 22 during ejection is preferably from 3 m/s to 15 m/s.

These are suitable requirements for suppressing scattering of the droplet 22 after its landing and for ejecting a desired volume of the droplet 22 efficiently and accurately.

Overview of Liquid-State Material

The composition of the liquid-state material (ink) in a preferred example will be described.

The liquid-state material is a liquid dispersion in which a solid component including conductive fine particles and a binder is dispersed in a dispersion medium. The liquid-state material is also referred to as an ink, or an ink composition. Note that the liquid-state material may further contain a surfactant.

The conductive fine particles are, for example, preferably metal nanoparticles composed of one or more selected from the group consisting of an elemental metal, an alloy or compound containing a metal element, or a mixture thereof. Specific examples include an elemental metal, or an alloy, a compound, or a mixture of an element, selected from the group consisting of Li, Be, B, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po and At.

Examples of the compound containing a metal element include TiO₂, ZnO, SnO₂, ITO, ZrO₂, SiOₓ, MgO, Al₂O₃, CeO₂, Bi₂O₃, Mn₃O₄, Y₂O₃, WO₃, Ta₂O₅, Nb₂O₅, and La₂O₃. However, the compound containing a metal element is not limited to the examples above and may be, for example, an oxide of a metal selected from the group consisting of silver, copper, nickel, palladium, iron, aluminum, tin, and zinc.

Also, one type of conductive fine particles may be used alone, or two or more types thereof may be used in combination. In a preferred example, a material of the conductive fine particles is preferably a noble metal such as gold, silver, platinum, copper, palladium, iridium, rhodium, osmium, or ruthenium, a transition metal such as nickel, or an amphoteric metal such as tin, and more preferably silver.

Furthermore, examples of a shape of the conductive fine particles include a spherical shape and a substantially spherical shape. Note that the shape of the conductive fine particles is not limited to these shapes, and the conductive fine particles may be any metal nanoparticles.

Average Particle Size of Conductive Fine Particles

From the viewpoint of dispersion stability, an average particle size of the conductive fine particles is preferably 500 nm or less, more preferably 250 nm or less, even more preferably 200 nm or less, and further more preferably 50 nm or less. Meanwhile, from the viewpoint of ease of production, the average particle size of the conductive fine particles is preferably 1 nm or more.

Among these, from the viewpoint of making a layer formed using the liquid-state material exhibit excellent conductivity, the conductive fine particles are preferably metal nanoparticles having an average particle size of from 1 nm to 500 nm, more preferably silver nanoparticles having an average particle size of from 1 nm to 200 nm.

Further, a content of the conductive fine particles in the liquid-state material is preferably, for example, 0.01 mass % or more, 0.05 mass % or more, 0.5 mass % or more, 5 mass % or more, 10 mass % or more, 20 mass % or more, 30 mass % or more, or 50 mass % or more, and is preferably 95 mass % or less, 90 mass % or less, 80 mass % or less, 70 mass % or less, or 50 mass % or less, relative to a total mass (100 mass %) of the liquid-state material.

The binder has a function of improving the adhesion of the layer formed using the liquid-state material with respect to the base material. The binder can also improve the strength of the layer formed using the liquid-state material. One type of the binder may be used alone, or two or more types thereof may be used in combination.

Examples of the binder include acrylic resins, polyesters, polyurethanes, polyethylene resins, polypropylene, polystyrene, polyvinyl pyrrolidone, polyethylene glycol, polyamides (e.g., water-soluble nylon, etc.), polyepoxy, polyvinyl alcohol, polysaccharides, proteins, polyethylenimine, polystyrene sulfonates, aromatic polyamides, carboxymethyl cellulose, cellulose nanofibers, and chitin nanofibers.

An amount of the binder is, for example, preferably 0.5 parts by mass or more, more preferably 1 part by mass or more, even more preferably 3 parts by mass or more, and preferably 50 parts by mass or less, more preferably 25 parts by mass or less, per 100 parts by mass of the conductive fine particles.

The dispersion medium has a function of adjusting the coating properties of the liquid-state material. One type of the dispersion medium may be used alone, or two or more types thereof may be used in combination.

Examples of the dispersion medium include water by itself or a liquid mixture of water and a polar organic solvent. In other words, the liquid-state material contains water in a composition thereof.

In these water-containing polar solvents, dispersibility is easily ensured by electrostatic repulsion between the conductive fine particles. Examples of the polar organic solvent include a polar organic solvent having an SP value, known as a solubility parameter, of 9.5 or greater. More specific examples include a polar organic solvent miscible with water, such as methanol, ethanol, propanol, acetone, acetonitrile, dimethylacetamide, dimethylformamide, dimethyl sulfoxide, dioxane, phenol, cresol, ethylene glycol, propylene glycol, butylene glycol, diethylene glycol, triethylene glycol and glycerin, as well as 2-ethylhexanol.

The surfactant is preferably a fluorosurfactant. By adding a fluorosurfactant to the liquid-state material, the coating properties of the liquid-state material with respect to various base materials, such as a base material made of a cyclic olefin resin, can be improved.

In addition, compared to a silicone surfactant or the like, a fluorosurfactant does not contaminate surrounding devices during drying of the liquid-state material. The use of a fluorosurfactant can also increase the conductivity of the layer formed using the liquid-state material compared to the case of using a silicone surfactant or the like. Furthermore, the use of a fluorosurfactant increases the Y value in the Yxy color space (that is, increases the metallic feel) of the layer formed using the liquid-state material compared to the case of using a silicone surfactant or the like.

Examples of the fluorosurfactant include an anionic fluorosurfactant, a cationic fluorosurfactant, an amphoteric fluorosurfactant, and a nonionic fluorosurfactant. Among these, the fluorosurfactant is preferably a nonionic fluorosurfactant from the viewpoint of sufficiently improving the coating properties of the liquid-state material and sufficiently ensuring the dispersibility of the conductive fine particles in the dispersion medium.

Furthermore, the fluorosurfactant preferably has a perfluoroalkenyl group or a perfluoroalkyl group, more preferably a perfluoroalkenyl group. The use of the fluorosurfactant having the above-mentioned group can sufficiently improve the coating properties of the liquid-state material. The use of the fluorosurfactant having the above-mentioned group can also sufficiently increase the conductivity of the layer formed using the liquid-state material. Furthermore, the fluorosurfactant is preferably a polyoxyethylene ether having an ethylene oxide chain. The use of the fluorosurfactant having the above-mentioned structure can sufficiently improve the coating properties of the liquid-state material. The use of the fluorosurfactant having the above-mentioned structure can also sufficiently increase the conductivity of the layer formed using the liquid-state material. Note that an average number of added moles of ethylene oxide (EO) is preferably 25 or less, more preferably 12 or less, still more preferably 10 or less, and particularly preferably 8 or less.

Examples of the fluorosurfactant include the FTERGENT M series, available from Neos Company Limited, such as FTERGENT 251, FTERGENT 208M, FTERGENT 212M, FTERGENT 215M, and FTERGENT 250, as well as the SURFLON series, available from AGC Seimi Chemical Co., Ltd., such as SURFLON S-211, SURFLON S-221, SURFLON S-231, SURFLON S-232, SURFLON S-233, SURFLON S-241, SURFLON S-242, SURFLON S-243, and SURFLON S-386.

Note that an amount of the fluorosurfactant in the liquid-state material is preferably 0.01 parts by mass or more, more preferably 0.05 parts by mass or more, and even more preferably 0.08 parts by mass or more, and is preferably 0.3 parts by mass or less, more preferably 0.2 parts by mass or less, and even more preferably 0.12 parts by mass or less, per 100 parts by mass of the dispersion medium. When the content of the fluorosurfactant is greater than or equal to the lower limit described above, the coating properties of the liquid-state material can be sufficiently improved, and the layer formed using the liquid-state material can sufficiently exhibit the desired characteristics. Accordingly, the conductivity of the layer formed using the liquid-state material can be sufficiently increased. Furthermore, when the content of the fluorosurfactant is equal to or less than the upper limit described above, the adhesion between the layer formed using the liquid-state material and the base material 1 can be increased.

Viscosity and Surface Tension of Liquid-State Material

Furthermore, a viscosity of the liquid-state material is preferably from 1 mPa·s to 10 mPa·s. The reasoning is as follows. When using a droplet ejecting method to eject the liquid-state material, in a case in which the viscosity of the liquid-state material is less than 1 mPa·s, the area around the nozzle is easily contaminated by the outflowing liquid-state material; meanwhile, in a case in which the viscosity of the liquid-state material is more than 10 mPa·s, the frequency of clogging of the nozzle hole 18 increases, making it difficult to eject droplets smoothly.

Furthermore, a surface tension of the liquid-state material is preferably in a range of from 20 mN/m to 40 mN/m. The reasoning is as follows. When using a droplet ejecting method to eject the liquid-state material, in a case in which the surface tension of the liquid-state material is less than 20 mN/m, the wettability of the liquid-state material composition with respect to the nozzle surface is increased, making flight deviation likely to occur; meanwhile, in a case in which the surface tension of the liquid-state material is greater than 40 mN/m, it becomes difficult to control the ejection volume and ejection timing because the shape of the meniscus at the tip of the nozzle hole 18 is not stable.

The surface tension can be adjusted by adding a tiny amount of a fluorine-based, silicone-based, or nonionic surface tension modifier to the liquid-state material. The nonionic surface tension modifier improves wettability of the liquid-state material with respect to the base material 1, improves the leveling properties of the resulting film, and helps to prevent the occurrence of blisters, the orange peel effect, or the like in the resulting coating film. Furthermore, the liquid-state material may contain an organic compound such as an alcohol, an ether, an ester, a ketone, or the like as necessary.

Overview of Base Material

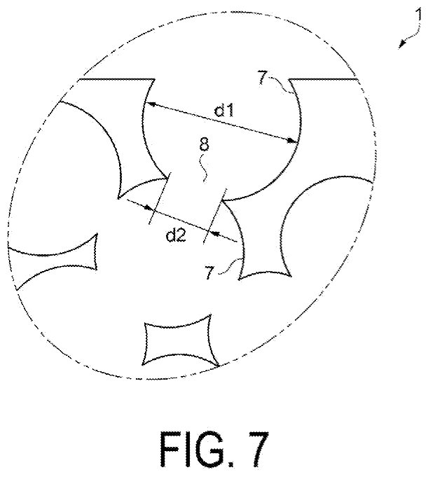

FIG. 7 is an enlarged view of a portion K in FIG. 2.

As described above, the base material 1 is a polyimide substrate having a porous structure, and the base material 1 has a plurality of cavities 7 and communication holes 8 via which adjacent cavities 7 communicate with each other.

As described above, according to the description of JP-A-2017-226777, an average cavity diameter d1 of the cavities 7 may be from 10 nm to 2500 nm. However, when the porous base material is used as a wiring substrate, the average cavity diameter d1 of the cavities 7 is preferably from 10 nm to 150 nm, more preferably from 30 nm to 100 nm. The reasoning is as follows. When the cavity diameter is too large, the amount of the liquid-state material that has entered the base material 1 (absorption amount) is too large, resulting in a smaller amount of solid component remaining on the surface. Meanwhile, when the cavity diameter is too small, the amount of the liquid-state material that has entered the base material 1 is too small, resulting in a weaker adhesion strength.

Also, an average cavity diameter d2 of the communication holes 8 is preferably both less than the average cavity diameter d1 of the cavities 7 and less than or equal to the average particle size of the conductive fine particles. In other words, the base material 1 contains a plurality of cavities 7 formed therein and the communication holes 8 via which the cavities 7 communicate with each other, and the average cavity diameter d2 of the communication holes 8 is less than or equal to the average particle size of the conductive fine particles. This is to make it easy for the dispersion medium to enter the communication holes 8 while making it hard for the solid component to pass through the communication holes 8, and to achieve the optimum balance among the absorption amount of the dispersion medium by the base material 1, the amount of the solid component that enters the base material 1 and exerts an anchoring effect, and the amount of the solid component that remains on the surface of the base material 1 and becomes the conductive pattern itself.

A thickness of the base material 1 is preferably from 30 μm to 100 μm. This is to ensure the strength of the base material 1 as a wiring substrate. Note that, for example, the base material 1 may be overlaid on a rigid substrate such as a silicon substrate and used. In other words, the base material 1 may be reinforced by backing with a rigid substrate. In addition, when not reinforced, the base material 1 can be made flexible while maintaining the strength of a wiring substrate, and can be bent or deformed and used.

### EXAMPLES

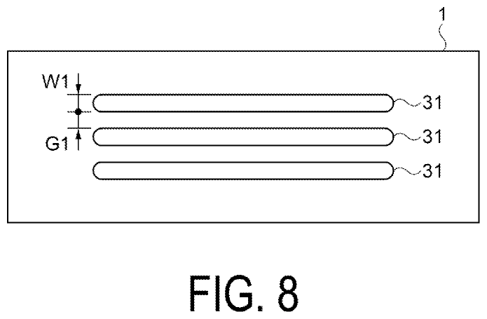

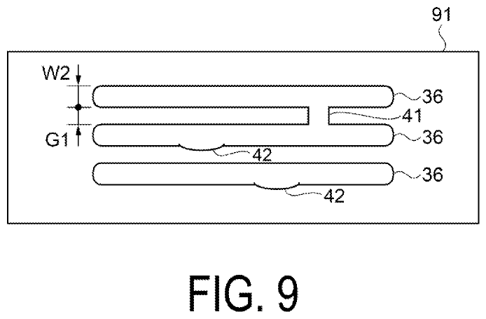

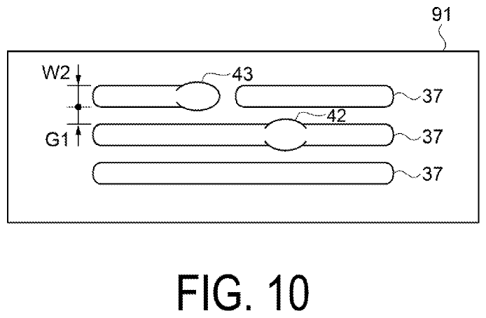

FIG. 8 is a plan view illustrating a conductive pattern created by the formation method according to an example. FIG. 9 and FIG. 10 are plan views illustrating a conductive pattern according to a comparative example.

A conductive pattern 31 illustrated in FIG. 8 was formed as follows.

First, a composition of the liquid-state material will be described.

Silver particles having an average particle size of 25 nm were used as the conductive fine particles. The content of the conductive fine particles was approximately 20 mass % with respect to the total mass (100 mass %) of the liquid-state material.

A polyester resin was used as the binder.

The dispersion medium was mainly composed of approximately 50 mass % of water and approximately 28 mass % of a glycol based on the total mass of the liquid-state material, with a polyol, an alcohol, a surfactant, and the like further added.

The liquid-state material having the composition described above has a viscosity of approximately 4 mPa·s and a surface tension of approximately 30 mN/m.

Referring back to FIG. 2,

the thickness of the base material 1 was set to 50 μm, and the average cavity diameter d1 (FIG. 7) of the cavities 7 was set to approximately 30 nm. The porosity, which is the ratio of the cavities 7 in the base material 1, was set to approximately 70%.

As illustrated in FIG. 1, the droplet ejecting head 10 of FIG. 6 was used to continuously eject the droplets 22 onto the base material 1. The nozzle diameter of the nozzle hole 18 (FIG. 6) in the droplet ejecting head 10 was set to approximately 20 μm.

The volume of the droplet 22 ejected every time from the droplet ejecting head 10 was set to approximately 2 pl, and the flying speed of the droplet 22 during ejection was set to approximately 10 m/s.

As illustrated in FIG. 8, droplets 22 were ejected from the droplet ejecting head 10, resulting in three linear conductive patterns 31 printed on the surface of the base material 1.

Then, the base material 1 on which the conductive patterns 31 were printed was heat-treated. The heat treatment was carried out at approximately 120° C. for 1 hour. The heat treatment was performed by placing the base material 1 on a hot plate set to 120° C.

A width W1 of the conductive pattern 31 thus formed was approximately 27 μm. A gap G1 between adjacent conductive patterns 31 was approximately 30 μm.

FIG. 9 is a view for comparison illustrating a case in which a conductive pattern 36 was formed on the base material 91 that is plain and non-porous under the same conditions as described above. The base material 91 is a 50-μm plain polyimide substrate.

When a droplet is ejected onto the base material 91 that is plain, as described in FIG. 4, there is almost no entry of the liquid-state material into the base material 91, and thus, the droplet that has landed spreads on the surface of the base material 91, resulting in a wide pattern. As such, a width W2 of the conductive pattern 36 was 40 μm or greater. Furthermore, a short-circuit portion 41 was formed between adjacent conductive patterns 36 via the gap G1 that is approximately 30 μm. In addition, on both the conductive pattern 36 at the center and the conductive pattern 36 at the bottom, a bulge 42 in which the width of the pattern was locally increased has occurred. The bulge 42 is accumulated liquid, and the short-circuit portion 41 is a result of the growth of the bulge 42.

FIG. 10 is a diagram illustrating an aspect of a defect different from the defect mode in FIG. 9, in which the conditions of forming a conductive pattern 37 are the same conditions as described above. In the conductive pattern 37 of FIG. 10, a disconnected portion 43 that is a result of a bulge has occurred. As described above, when a bulge occurs, a fatal defect such as a short circuit or disconnection may occur.

In comparison, despite being a fine pattern, the conductive patterns 31 formed on the base material 1 that is porous in FIG. 8 according to the present embodiment had clear edges and no bulges. Further, it was confirmed that the adhesion strength of the conductive patterns 31 was higher than the adhesion strength of the conductive patterns 36 provided on the base material 91 that is plain. It was also confirmed that the specific resistance value of the conductive patterns 31 was equivalent to the specific resistance value of the conductive patterns 36 provided on the base material 91 that is plain, enabling the conductive patterns 31 to be used as electrical wiring.

Also, although not illustrated, it has been confirmed that the use of the base material 1 that is porous according to the present example is superior even when compared to the use of the base material having an accommodation layer according to JP-A-2004-6578. More specifically, even when the base material having an accommodation layer is used, bulging and bleed-through are confirmed, although the severity is less than when the base material 91 that is plain is used. This is thought to be because the base material having an accommodation layer has no communication holes and absorbs less dispersion medium than the base material 1 that is porous does, resulting in wetting and spreading of the solid component on the surface.

### Modified Example

In the description above, the heat treatment was carried out at approximately 120° C. for 1 hour. However, the heat treatment is not limited to these conditions, and the temperature and time can be any as long as the temperature is within the heat-resistant temperature range of the base material 1 and as long as the conductive fine particles can be sintered to become one piece. Even when the heat treatment is carried out under these conditions, the dispersion medium can be volatilized by the heat treatment, and the conductive fine particles can be sintered to form a conductive pattern. Also, the heat treatment may be performed using an electric furnace or by lamp annealing.

Furthermore, the surface of the base material 1 may be subjected to a liquid repellent treatment. In the liquid repellent treatment, for example, the surface of the base material 1 is subjected to a plasma treatment using a fluorine-containing gas, thereby modifying the surface to be liquid-repellent. In this way, the wetting and spreading of the droplets after landing is further suppressed because of the liquid repellent treatment of the surface of the base material 1, and thus a finer conductive pattern can be formed. Furthermore, the base material 1 may be treated with a coating agent containing a fluorosilane-based material by dipping, spraying, or another coating method. Since the inner surfaces of the cavities 7b and 7c inside the base material 1 are also subjected to the liquid repellent treatment, wetting and spreading of the solid component on the surface of the base material 1 is suppressed.

Alternatively, the surface of the base material 1 may be subjected to a hydrophilic treatment. In the hydrophilic treatment, for example, a highly hydrophilic functional group (OH group) is formed at the surface of the base material 1 by an oxygen plasma treatment. Note that a hydrophilic film may be formed by a chemical reaction such as UV irradiation, thermal curing, or moisture curing. In this way, the spreading of the droplets after landing increases because of the hydrophilic treatment of the surface of the base material 1, and the amount of the liquid-state material that enters the base material 1 increases; as such, the adhesion of the conductive pattern after sintering is improved.

As described above, according to the method of forming a conductive pattern of the present embodiment, the following effects can be obtained.

A method of forming a conductive pattern includes forming a conductive pattern by ejecting a liquid-state material containing conductive fine particles onto a base material 1 that is porous, wherein the conductive fine particles have an average particle size of from 1 nm to 200 nm, and the base material 1 contains a plurality of cavities 7 formed therein and communication holes 8 via which the plurality of cavities 7 communicate with each other, an average diameter d2 of the communication holes 8 being less than or equal to the average particle size of the conductive fine particles.

According to this formation method, in the droplet 22a that has landed on the base material 1 having a porous structure, the dispersion medium with a high fluidity enters cavities 7b and 7c located inside the base material 1 through the communication holes 8 and is rapidly absorbed, while a large amount of the solid component, such as the conductive particles and the binder, remains on the surface of the base material 1. Here, since a large portion of the dispersion medium with a high fluidity is absorbed by the cavities 7, wetting and spreading of the solid component on the surface is suppressed, and the diameter of the droplet at the time of landing is substantially maintained. As a result, the conductive pattern 31 having a desired two-dimensional shape can be obtained.

In addition, in the liquid-state material that has entered the cavities 7a, nearly all conductive particles are not able to pass through the communication holes 8 and remain in the cavities 7a facing the surface of the base material 1. After being sintered by the heat treatment, the solid component including the conductive particles that remain in the cavities 7a exerts an anchor effect and plays a role of improving the adhesion of the conductive pattern 31 with respect to the base material 1.

As such, a method of forming a conductive pattern having excellent adhesion with respect to a substrate can be provided. Such a base material 1 can be suitably used as a flexible substrate. This is because such a base material 1 ensures the adhesion of a conductive pattern even at a bent portion, and thus satisfies the mechanical and electrical reliability required for a flexible substrate.

Furthermore, the viscosity of the liquid-state material is preferably from 1 mPa·s to 10 mPa·s. This makes the droplets 22 flow easily even after landing on the base material 1, and thus the dispersion medium is quickly absorbed into the plurality of cavities 7. As such, wetting and spreading of the solid component on the surface is suppressed, and the conductive pattern 31 having a desired two-dimensional shape can be obtained.

Furthermore, the surface tension of the liquid-state material is preferably from 20 mN/m to 40 mN/m.

This makes the shape of the meniscus at the tip of the nozzle hole 18 stable, and as such, it becomes easy to control the ejection volume and ejection timing of the droplet 22, and the droplet 22 can be ejected along a desired trajectory.

Furthermore, the liquid-state material may contain water in a composition thereof.

This makes it possible to optimize the viscosity and surface tension of the liquid-state material by adjusting the amount of water.

Moreover, the base material 1 may be subjected to a liquid repellent treatment.

In this way, the wetting and spreading of the droplets after landing is further suppressed because of the liquid repellent treatment of the surface of the base material 1, and thus a finer conductive pattern can be formed.

Furthermore, a droplet volume of the liquid-state material ejected every time is preferably from 0.2 pl to 20 pl.

This makes it possible to efficiently form a desired conductive pattern by adjusting the droplet volume in accordance with the shape of the conductive pattern.

Furthermore, the nozzle diameter of the nozzle hole 18 in the droplet ejecting head 10 serving as the ejecting unit that ejects the liquid-state material is preferably from 10 μm to 25 μm.

Also, the flying speed of the droplet 22 when the liquid-state material is ejected is preferably from 3 m/s to 15 m/s.

This makes it possible to eject a desired volume of the droplet 22 efficiently and accurately and to suppress scattering of the droplet after landing.

### Second Embodiment

### Application in Electronic Apparatus

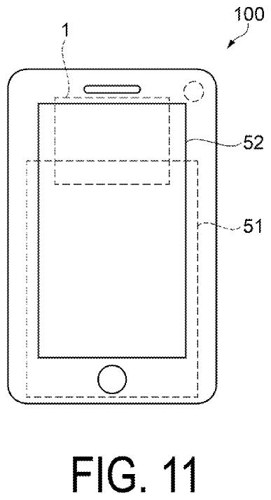

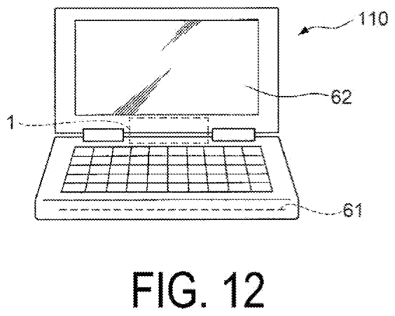

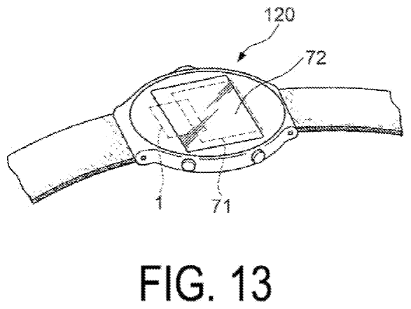

FIG. 11 is an external view of a smart phone. FIG. 12 is an external view of a laptop. FIG. 13 is an external view of a smart watch.

The base material 1 having a conductive pattern as described in the embodiment above can be applied to various electronic apparatuses as a substrate 1 or a substrate 86.

FIG. 11 is an external view of a smart phone 100 that is an electronic apparatus.

The smart phone 100 includes a main substrate 51 mounted with a processor and a memory, a display unit 52 provided with a touch panel, and the like.

The main substrate 51 and the display unit 52 are electrically coupled by the substrate 1, which is a flexible wiring substrate. The substrate 1 is the base material 1 having a conductive pattern described in the above embodiment serving as a flexible substrate.

FIG. 12 is an external view of a laptop 110 that is an electronic apparatus.

The laptop 110 includes a main substrate 61 mounted with a processor and a memory, a display unit 62 including a liquid crystal panel, and the like.

The main substrate 61 and the display unit 62 are electrically coupled by the substrate 1, which is a flexible wiring substrate. The substrate 1 is the base material 1 having a conductive pattern described in the above embodiment serving as a flexible substrate.

FIG. 13 is an external view of a smart watch 120 that is an electronic apparatus.

The smart watch 120 includes a main substrate 71 mounted with a processor and a memory, a display unit 72 including an organic EL (electro luminescence) panel, and the like. The main substrate 71 and the display unit 72 are electrically coupled by the substrate 1, which is a flexible wiring substrate. The substrate 1 is the base material 1 having a conductive pattern described in the above embodiment serving as a flexible substrate.

These electronic apparatuses are provided with the substrate 1 of the above embodiment which has excellent mechanical and electrical reliability, and thus these electronic apparatuses can display stably.

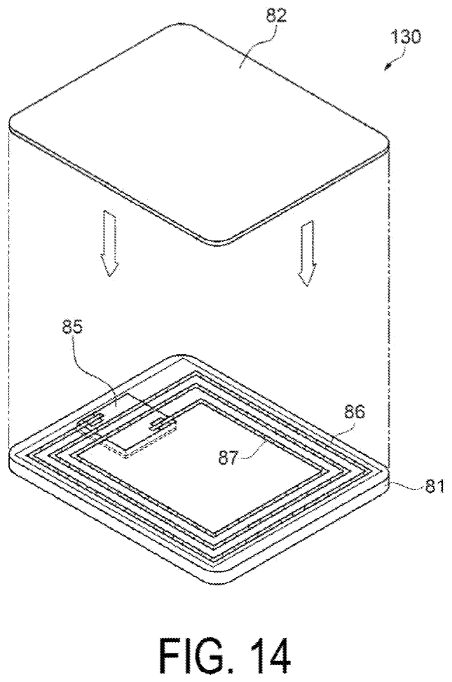

FIG. 14 is an exploded perspective view of a non-contact card medium.

A non-contact card medium 130, which is an electronic apparatus, supplies electric power and/or communicates data with an external transceiver (not illustrated) by using at least one of electromagnetic waves and capacitive coupling.

The non-contact card medium 130 includes a semiconductor integrated circuit chip 85 and the substrate 86 that functions as an antenna housed in a housing composed of a card base 81 and a card cover 82. The substrate 86 is a sheet-shaped loop antenna in which an antenna wiring 87 having a rectangular spiral shape is provided on the base material 1 having a conductive pattern described in the above embodiment.

The non-contact card medium 130 is provided with the substrate 86 of the above embodiment which has excellent mechanical and electrical reliability, and thus the non-contact card medium 130 can function stably as an antenna.

What is claimed is:

1. A method of forming a conductive pattern comprising forming a conductive pattern by ejecting a liquid-state material containing conductive fine particles onto a porous base material, wherein
the conductive fine particles have an average particle size of from 1 nm to 200 nm, and
the porous base material is formed with a plurality of cavities and includes communication holes through which the plurality of cavities are in communication, an average diameter of the communication holes being less than or equal to the average particle size of the conductive fine particles.

2. The method of forming a conductive pattern according to claim 1, wherein
a viscosity of the liquid-state material is from 1 mPa·s to 10 mPa·s.

3. The method of forming a conductive pattern according to claim 1, wherein
a surface tension of the liquid-state material is from 20 mN/m to 40 mN/m.

4. The method of forming a conductive pattern according to claim 1, wherein
the liquid-state material contains water in a composition thereof.

5. The method of forming a conductive pattern according to claim 1, wherein
the porous base material is subjected to a liquid repellent treatment.

6. The method of forming a conductive pattern according to claim 1, wherein
a droplet volume of the liquid-state material ejected every time is from 0.2 pl to 20 pl.

7. The method of forming a conductive pattern according to claim 1, wherein
a nozzle diameter in an ejecting unit that ejects the liquid-state material is from 10 μm to 25 μm.

8. The method of forming a conductive pattern according to claim 1, wherein
a droplet flying speed of the liquid-state material ejected is from 3 m/s to 15 m/s.
